(19) United States
(12) Patent Application Publication
(10) Pub. No.: US 2010/0163861 A1
(43) Pub. Date: Jul. 1, 2010

(54) METHOD AND APPARATUS FOR OPTICALLY TRANSPARENT TRANSISTOR

(75) Inventor: Paul W. Brazis, JR., South Elgin, IL (US)

Correspondence Address: MOTOROLA, INC., 1303 EAST ALGONQUIN ROAD, IL01/3RD, SCHAUMBURG, IL, 60196, US

(73) Assignee: Motorola, Inc., Schaumburg, IL (US)

(21) Appl. No.: 12/344,775

(22) Filed: Dec. 29, 2008

(51) Int. Cl. H01L 29/12; H01L 21/033

(52) U.S. Cl. 257/43; 438/104; 257/E21.033; 257/E29.068

(57) ABSTRACT

A method and apparatus for an optically transparent field effect transistor on a substrate. The gate electrode, the dielectric, the semiconducting layer, the source electrode, and the drain electrode are optically transparent layers of nanoparticles that are formed using one or more graphic arts printing processes. The dielectric layer is in contact with the gate electrode, the semiconducting layer is in contact with the dielectric layer, and the source and drain electrodes are in contact with the semiconducting layer.

### FIELD OF THE INVENTION

The present invention relates generally to semiconductor devices, and more particularly, to optically transparent transistors containing nanoparticles printed using a graphic arts process.

### BACKGROUND

Thin film transistors are widely used as switching elements in electronics, for example, in active-matrix liquid crystal displays, smart cards, and a variety of other electronic devices and components. There is a growing interest in depositing thin film transistors on plastic or flexible substrates, because these supports would be more mechanically robust, lighter weight, and lower cost. Semiconductor materials that are simpler to process, especially those that are soluble in organic or aqueous solvents and capable of being applied to large areas by relatively simple processes, open up a wider range of substrate materials, including plastics, for flexible electronic devices. Furthermore, additive solution processes have the opportunity to reduce materials cost by only applying materials where they are needed. Thus, thin film transistors made of printable semiconductor materials can be viewed as a potential key technology for circuitry in various electronic devices or components such as display backplanes, portable computers, pagers, memory elements in transaction cards, and identification tags, where ease of fabrication, mechanical flexibility, and/or moderate operating temperatures are important considerations. The microelectronics industry is also undertaking efforts to fabricate electronic devices (e.g., diodes and transistors) that are transparent to the portion of the electromagnetic spectrum that is visible to the human eye. Circuits made of such devices would offer unique opportunities for innovation or improvement of consumer, automotive, and military electronics. However, conventional transistors used in display backplanes tend to be optically opaque, resulting in loss of transmission efficiency. Current printable transistors have one or more opaque or colored elements such as silver paste, organic semiconductors, or sputtered metals. Although a transparent transistor has been demonstrated, the process utilized exotic materials such as InGaZnO requiring complicated, high temperature processes (such as pulsed laser deposition). These are not amenable to scaling towards the high volume manufacture required to produce low cost devices or very large area devices. It would be a significant addition to the art if a transparent transistor that does not require high temperature treatments could be made in large volumes at low cost.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a partial cross-sectional view of an optically transparent transistor, in accordance with some embodiments of the invention.

FIG. 2 is a flow chart of one method used to form an optically transparent transistor, in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method and apparatus components related to transparent transistors. Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element. The term “gate” generally refers to the insulated gate terminal of a three terminal field effect transistor (FET) when used in the context of a transistor circuit configuration. “Substantially insulating” can include insulating materials and semi-insulating materials. “Substantially transparent” generally denotes a material or construct that does not absorb a substantial amount of light in the visible portion (and/or infrared portion in certain variants) of the electromagnetic spectrum. In describing the invention, the term “transparent” is understood to mean optically transparent to a human observer, that is, having an optical transmission of at least about 50% across the visible and/or infrared portion of the electromagnetic spectrum. The preceding term descriptions are provided solely to aid the reader, and should not be construed to have a scope less than that understood by a person of ordinary skill in the art or as limiting the scope of the appended claims.

A method and apparatus for an optically transparent field effect transistor on a substrate is disclosed. The gate electrode, the dielectric, the semiconducting layer, the source electrode, and the drain electrode are optically transparent layers of nanoparticles that are formed using one or more graphic arts printing processes. The dielectric layer is in contact with the gate electrode, the semiconducting layer is in contact with the dielectric layer, and the source and drain electrodes are in contact with the semiconducting layer. In certain embodiments, the transistor structure as a whole (and/or individual components of the transistor) may exhibit an optical transmission of at least about 50%, more particularly at least about 70%, and most particularly at least about 90%, across the visible portion (and/or infrared portion in certain variants) of the electromagnetic spectrum.

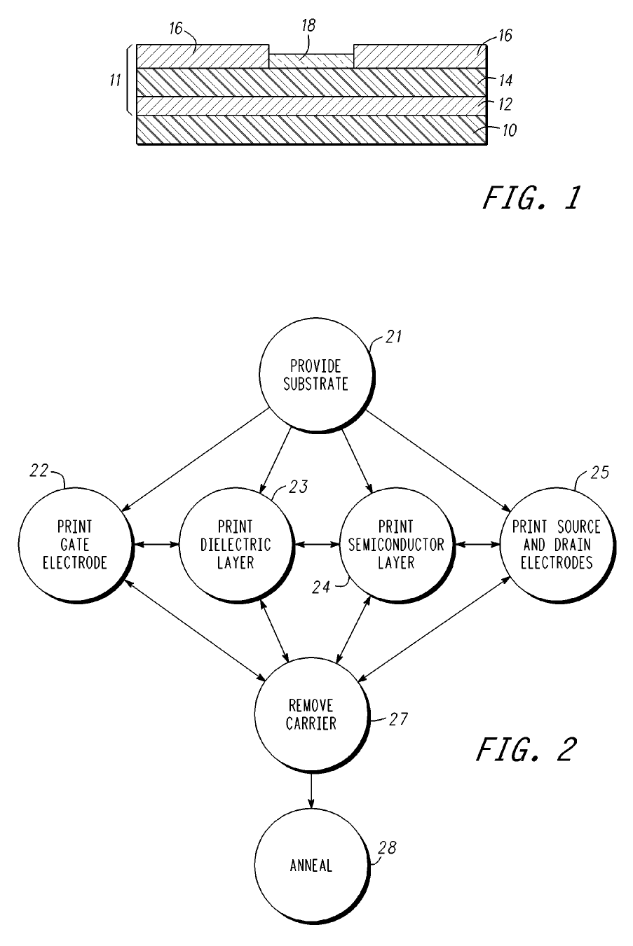

Referring now to FIG. 1, the substrate 10 for the transparent transistor 11 may be rigid or flexible, for example, silicon, glass, polymers, etc. In various embodiments, the substrate is a flexible polymer, a rigid polymer, a transparent polymer, or combinations thereof, such as polyamide, polyimide, polyetherimide, polysiloxane, polyurethane, polyamide-imide, polyester, polyacrylate, paper, etc. These films are flexible, and provide various degrees of transmittance of visible light. However, for various reasons, one may choose to utilize a non-transparent substrate. The optically transparent transistor structure 11 is formed on the substrate 10. A gate electrode 12 is situated on the substrate, and is an optically transparent and electrically conductive layer of indium tin oxide (ITO) nanoparticles or antimony tin oxide (ATO) nanoparticles. In one embodiment, the gate electrode layer may also contain a small amount of a binding agent, such as poly-4-vinylphenol, also called polyvinyl phenol (PVP). PVP is used to promote adhesion between the nanoparticles and the substrate, and to help bind the nanoparticle together to form a cohesive film. PVP levels less than 5% by weight, and preferably less than 2% by weight, may be employed, because excess amounts of polymer binding agent can inhibit interparticle contact between the nanoparticles and degrade electrical performance. Nanoparticles are well known to have a very high ratio of surface area to volume. The properties of these materials change as their size approaches the nanoscale and as the percentage of atoms at the surface of a material becomes significant. Each nanoparticle consists of a single crystal that is roughly spherical providing improved packing of particles after deposition, the extremely small size of the nanoparticles also enables them to be easily dispersed in carrier solvents. In one embodiment, the nanoparticle shape is selected such that the ratio of the largest dimension to the smallest dimension is between 1.0 and about 1.5. Metal oxide nanoparticles are commercially available, with many tons per year used in products such as cosmetics, sunscreen, paints, and polishes. In order to maintain a reasonable level of optical transparency, the particle size of the nanoparticles is less than 100 nanometers, more particularly in the range of 20-75 nanometers, with sizes of approximately 20 nanometers being particularly advantageous. In one embodiment, the gate electrode is a vacuum deposited metal oxide, such as ITO or ATO, so long as it is transparent. Situated on the gate electrode 12 is a dielectric layer 14, which consists of an electrically insulating, optically transparent layer of aluminum oxide nanoparticles or silicon dioxide nanoparticles. PVP or some other suitable binding agent can be optionally added to the dielectric layer 14 to impart greater mechanical structure, as described previously. Situated on the dielectric layer 14 are optically transparent and electrically conductive source and drain electrodes 16. These electrodes, like the gate electrode, consist of indium tin oxide nanoparticles or antimony tin oxide nanoparticles, and may also contain a small amount of a binding agent. The source and drain electrodes are separated and in contact with the dielectric layer 14 and an optically transparent semiconducting layer 18, which consists of nanoparticles of a semiconductive material such as zinc oxide, tin oxide, zinc sulfide or gallium nitride.

The structure depicted in FIG. 1 is but one arrangement, however, and the dielectric layer, the gate electrode, the semiconducting layer, the source electrode, and the drain electrode may be arranged in a number of ways, as long as the gate electrode and the semiconducting layer both contact the dielectric layer, and the source electrode and the drain electrode both contact the semiconducting layer.

Having described the structure of an optically transparent transistor, details of the materials and processes used to create such a transistor are now revealed in the flow chart of FIG. 2. A smooth dielectric material, for example a polymer film, is used 21 as the substrate for the device. To form the gate electrode 22, a printable composition contains nanoparticles of indium tin oxide or antimony tin oxide suspended in a volatile carrier, such as a liquid solvent, at a concentration of at least 10% by weight. Concentrations of 20-30% by weight were found to be quite useful, and even higher concentrations can be employed if Theologically allowable in order to reduce the volume of carrier solvent used. The carrier does not dissolve the nanoparticles, but suspends them in a dispersion. Suspensions of nanoparticles are possible because the interaction of the particle surface with a carrier solvent is strong enough to overcome differences in density, which result in a material either sinking or floating in a liquid. Some solvents that can be used are primary alkyl alcohols, alkyl diols, alkyl polyols, water, alkyl glycol ethers, and alkyl glycol acetates. Prevention of particle agglomeration may be facilitated using an appropriate chemical additive as is well known in the suspension chemistry art. Although the carrier solvent is selected to provide sufficient (30% by weight) dispersion without significant use of other additives, surfactants and/or binding agents such as PVP may be employed to optimize the rheology and stability of the printable composition, and are carefully selected so as to not affect the device electrical performance. The printable composition is printed on the substrate using one or more well known graphic arts processes employing contact and non-contact printing methods such as spin coating, roller coating, curtain coating, spraying, gravure printing, screen printing, inkjet printing, flexo printing, offset lithography printing, and microdispensing, to form the gate electrode. These techniques are amenable to high speed printing, enabling low cost devices to be made, and are much less capital intensive than conventional vacuum deposition techniques. The printed deposit is then dried 27, for example by heating, to remove most or all of the carrier. Since the solvents enumerated above have a relatively low boiling point and are volatile below 150° C., the deposit does not need to be heated at high temperatures that may damage the substrate. Those skilled in the art of film technology will appreciate that removing a carrier does not always constitute removing every last molecule of material, but substantially removing enough so as to provide the desired end properties, such as, for example, creating an electrically stable film. The dielectric layer is formed 23 in a similar manner, using one or more of the graphics arts techniques, and a dispersion of aluminum oxide nanoparticles or silicon dioxide nanoparticles in a carrier. PVP or other polymers may be added to produce optimum film performance. The source and drain electrodes are formed 25 using a nanoparticle dispersion similar to that used to form the gate electrode. The semiconducting layer is also printed 24 in a like manner, using nanoparticle dispersions of a semiconductive material such as zinc oxide, tin oxide, zinc sulfide or gallium nitride. The semiconductor can be doped or undoped. Doping of the nanoparticles can be used to optimize device performance, however, undoped nanoparticle inks may be suitable for thin film transistor operation.

As the nanoparticle dispersions used to form the various layers contain volatile carriers, the carrier needs to be removed 27. This is generally accomplished by baking at elevated temperatures, but could also be removed by exposing the printed deposits to a vacuum at ambient temperature. This carrier removal may be accomplished after each printing operation, or after multiple prints, or after all layers have been deposited. An optional annealing treatment 28, comprising heating the transistor structure at elevated temperatures, for example in excess of 200 degrees Centigrade but less than the glass transition temperature of the substrate, may be employed to enhance the optical transparency of the various layers. This can increase the transparency as compared to an equivalent transistor that has not been annealed.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. An optically transparent field effect transistor situated on an insulating substrate, comprising:
a substantially transparent gate electrode consisting of indium tin oxide nanoparticles or antimony tin oxide nanoparticles;
a substantially transparent dielectric layer in contact with the substantially transparent gate electrode, comprising aluminum oxide or silicon dioxide nanoparticles dispersed in a polymer;
a substantially transparent semiconducting layer in contact with the substantially transparent dielectric layer, comprising nanoparticles of a wide bandgap doped or undoped material selected from the group consisting of zinc oxide, tin oxide, zinc sulfide and gallium nitride;
a substantially transparent source electrode in contact with the substantially transparent semiconducting layer, consisting of indium tin oxide nanoparticles or antimony tin oxide nanoparticles; and
a substantially transparent drain electrode in contact with the substantially transparent semiconducting layer, consisting of indium tin oxide nanoparticles or antimony tin oxide nanoparticles.

2. The optically transparent field effect transistor as described in claim 1, wherein the dielectric layer, the gate electrode, the semiconducting layer, the source electrode, and the drain electrode are in any sequence as long as the gate electrode and the semiconducting layer both contact the dielectric layer, and the source electrode and the drain electrode both contact the semiconducting layer.

3. The optically transparent field effect transistor as described in claim 1, wherein the insulating substrate is substantially transparent.

4. The optically transparent field effect transistor as described in claim 1, wherein nanoparticles have a diameter less than 100 nanometers.

5. The optically transparent field effect transistor as described in claim 1, wherein the indium tin oxide, antimony tin oxide, aluminum oxide, silicon dioxide, zinc oxide, tin oxide, zinc sulfide or gallium nitride nanoparticles further comprise a binding agent.

6. The optically transparent field effect transistor as described in claim 5, wherein the binding agent comprises polyvinyl phenol.

7. The optically transparent field effect transistor as described in claim 5, wherein the binding agent comprises less than 5% by weight of the nanoparticles.

8. An optically transparent field effect transistor situated on an insulating substrate, comprising:
a substantially transparent gate electrode consisting of a thin film of vacuum deposited indium tin oxide or antimony tin oxide;
a substantially transparent dielectric layer in contact with the substantially transparent gate electrode, comprising aluminum oxide or silicon dioxide nanoparticles dispersed in a polymeric binder;
a substantially transparent semiconducting layer in contact with the substantially transparent dielectric layer, comprising nanoparticles of a doped or undoped material selected from the group consisting of zinc oxide, tin oxide, zinc sulfide and gallium nitride;
a substantially transparent source electrode in contact with the substantially transparent semiconducting layer, consisting of indium tin oxide nanoparticles or antimony tin oxide nanoparticles; and
a substantially transparent drain electrode in contact with the substantially transparent semiconducting layer, consisting of indium tin oxide nanoparticles or antimony tin oxide nanoparticles; and
wherein the dielectric layer, the gate electrode, the semiconducting layer, the source electrode, and the drain electrode are in any sequence as long as the gate electrode and the semiconducting layer both contact the dielectric layer, and the source electrode and the drain electrode both contact the semiconducting layer.

9. The optically transparent field effect transistor as described in claim 8, wherein the insulating substrate is substantially transparent.

10. The optically transparent field effect transistor as described in claim 8, wherein nanoparticles have a diameter less than 100 nanometers.

11. The optically transparent field effect transistor as described in claim 8, wherein the indium tin oxide, antimony tin oxide, aluminum oxide, silicon dioxide, zinc oxide, tin oxide, zinc sulfide or gallium nitride nanoparticles further comprise a binding agent.

12. The optically transparent field effect transistor as described in claim 11, wherein the binding agent comprises polyvinyl phenol.

13. The optically transparent field effect transistor as described in claim 11, wherein the binding agent comprises less than 5% by weight of the nanoparticles.

14. A method of forming an optically transparent field effect transistor on an insulating substrate, utilizing graphic arts printing processes, comprising:
forming a substantially transparent gate electrode by printing a suspension of indium tin oxide or antimony tin oxide nanoparticles in a carrier solvent;
forming a substantially transparent dielectric layer by printing a suspension of aluminum oxide or silicon dioxide nanoparticles dispersed in a polymeric binder;
forming a substantially transparent semiconducting layer by printing a suspension of nanoparticles selected from the group consisting of zinc oxide, tin oxide, zinc sulfide and gallium nitride in a carrier solvent;
forming substantially transparent source and drain electrodes by printing a suspension of indium tin oxide or antimony tin oxide nanoparticles in a carrier solvent;
baking the transistor to substantially remove the carrier solvents; and
wherein forming the gate electrode, forming the dielectric layer, forming the semiconducting layer, forming the source and drain electrodes, and baking the transistor are in any sequence as long as the gate electrode and the semiconducting layer both contact the dielectric layer, and the source electrode and the drain electrode both contact the semiconducting layer.

15. The method of forming an optically transparent field effect transistor as described in claim 14, further comprising heating the optically transparent transistor sufficient to increase optical transparency.

16. The method of forming an optically transparent field effect transistor as described in claim 15, wherein heating the transistor comprises heating at a temperature greater than 200 degrees Centigrade.

17. The method of forming an optically transparent field effect transistor as described in claim 14, further comprising a binding agent in the suspension of indium tin oxide, antimony tin oxide, aluminum oxide, silicon dioxide, zinc oxide, tin oxide, zinc sulfide or gallium nitride nanoparticles.

18. The method of forming an transparent field effect transistor as described in claim 17, wherein the binding agent comprises polyvinyl phenol.

19. The method of forming an optically transparent field effect transistor as described in claim 17, wherein the binding agent comprises less than 5% by weight of the suspension.
